(19) United States
(12) Patent Application Publication
(10) Pub. No.: US 2024/0362380 A1
(43) Pub. Date: Oct. 31, 2024

(54) BUILDING PRODUCT MODELS THAT INDICATE SENSITIVITY TO ELECTROSTATIC DISCHARGE (ESD)

(71) Applicant: INTERNATIONAL BUSINESS MACHINES CORPORATION, ARMONK, NY (US)

(72) Inventors: Jacob Dixon, Rochester, MN (US); Steven Chandler Borrillo, Rochester, MN (US); Andrea Giovannini, Zurich (CH); Gandhi Sivakumar, Bentleigh (AU)

(21) Appl. No.: 18/306,300

(22) Filed: Apr. 25, 2023

(51) Int. Cl. G06F 30/27; G06Q 30/018

(52) U.S. Cl. CPC G06F 30/27; G06Q 30/018

(57) ABSTRACT

A computer-implemented method, a computer system and a computer program product build a product model that indicates an electrostatic discharge (ESD) sensitivity level. The method includes identifying a sensitive component in a model of an electronics device and mapping the sensitive component to a location in the electronics device. The method also includes obtaining ESD metadata for the sensitive component. In addition, the method includes determining an ESD voltage threshold for the sensitive component based on the ESD metadata for the sensitive component. Lastly, the method includes generating the product model of the electronics device, wherein the product model includes a plurality of sensitive components mapped to a plurality of locations in the electronics device and an indication of the ESD voltage threshold for each sensitive component at a respective mapped location in the electronic device.

### BACKGROUND

Embodiments relate generally to the field of electronics product compliance to electrostatic discharge (ESD) sensitivity requirements and, more specifically, to indicating ESD sensitivity levels at specific locations on product models of electronics devices.

Electronics devices, which are ubiquitous in today's world, may experience disruptions to expected functionality due to electrostatic discharge (ESD), which may range from hard errors, e.g., physical damage to the overall device or various components, to soft errors, e.g., bit errors, upsets or unwanted resets. As a result, many jurisdictions have compliance standards that require electronics devices to be tested for ESD before the devices may be sold in that jurisdiction. Because of these requirements and the labor-intensive processes needed to comply, it may be important to understand the sensitivity of an electronics device to ESD.

### SUMMARY

An embodiment is directed to a computer-implemented method for building a product model that indicates an electrostatic discharge (ESD) sensitivity level. The method may include identifying a sensitive component in a model of an electronics device and mapping the sensitive component to a location in the electronics device. The method may also include obtaining ESD metadata for the sensitive component from an ESD database. In addition, the method may include determining an ESD voltage threshold for the sensitive component based on the ESD metadata for the sensitive component. Lastly, the method may include generating the product model of the electronics device, where the product model includes a plurality of sensitive components mapped to a plurality of locations in the electronics device and an indication of the ESD voltage threshold for each sensitive component at a respective mapped location in the electronic device.

In another embodiment, the method may include transmitting the product model to an ESD test simulation system and applying, by the ESD test simulation system, ESD discharges to each respective mapped location in the electronics device.

In a further embodiment, the method may include monitoring user interactions with the product model, wherein a user selects the location in the electronics device on the product model and mapping the sensitive component to the location in the electronics device based on the user interactions.

In yet another embodiment, the method may include identifying an ESD regulatory specification in the ESD metadata, where the ESD regulatory specification includes a geographical region, and modifying the ESD voltage threshold based on the geographical region of the ESD regulatory specification.

In still another embodiment, the identifying the sensitive component in the model of the electronics device may use a machine learning model that predicts ESD test points for the electronics device based on an ESD regulatory specification and technical specifications of the electronics device.

In another embodiment, the determining the ESD voltage threshold for the sensitive component based on the ESD metadata for the sensitive component may use a machine learning model that predicts an ESD testing level for the sensitive component based on an ESD regulatory specification and historical ESD testing information for the electronics device.

In a further embodiment, the ESD database may comprise data selected from a group consisting of: historical ESD test data for the sensitive component, historical ESD test data for the electronics device, and at least one regulatory specification related to ESD.

In addition to a computer-implemented method, additional embodiments are directed to a computer system and a computer program product for building a product model that indicates an electrostatic discharge (ESD) sensitivity level.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 depicts a block diagram of an example computer system in which various embodiments may be implemented.

FIG. 2 depicts a flow chart diagram for a process that builds a product model that indicates an electrostatic discharge (ESD) sensitivity level according to an embodiment.

### DETAILED DESCRIPTION

Electronics devices, such as handheld devices, e.g., smartphones or tablet and laptop computers, and including more permanent computer or network architecture, e.g., computer servers, storage devices or networking equipment that may be rack-mounted in a commercial data center or similar dedicated area of any size, but also including household, medical, commercial or industrial appliances that may be built into larger structures, e.g., washing machines, dryers, HVAC equipment or microwave ovens, may be disrupted from properly functioning in the presence of electrostatic discharge (ESD). ESD, known colloquially as “static electricity,” is a sudden and momentary flow of electric current between two electrically charged objects caused by contact, an electrical short or dielectric breakdown. ESD can create spectacular electric sparks, such as a lightning storm, but also less dramatic forms which may be neither seen nor heard, yet still may be large enough to cause damage to sensitive electronic devices. ESD can cause harmful effects of importance in industry, including explosions in gas, fuel vapor and coal dust, as well as failure of solid-state electronics components such as integrated circuits, which may suffer permanent damage when subjected to high voltages. These potential disruptions may cause electronics manufacturers to establish electrostatic protective areas that may prevent charging, using measures such as grounding human workers, providing antistatic devices, and controlling humidity while near electronics devices.

To protect the devices and consumers, many jurisdictions, including but not limited to the European Union (EU) and South Korea, have enacted regulatory compliance standards that establish minimum ESD sensitivity levels that must be met to sell electronics devices in the market. In addition to these minimum standards, a manufacturer may also specify a compliance policy with respect to ESD in the interest of quality, such that the products sold by the manufacturer greatly exceed the standards set by any individual regulatory specification. As a result of the compliance standards or the compliance policy, extensive testing of electronics devices may be required before release of a product into the market. The conventional method of testing electronics devices for sensitivity to ESD involves subjecting each device to ESD using a manual ESD simulator, which may simulate ESD from a human or other ESD sources. The ESD is typically applied to different areas and components of the device to determine compliance with the predefined ESD specifications. This manual ESD testing may be labor intensive and, in the absence of prior knowledge, may require the manual determination of sensitive area or components within the device through trial and error and may also require multiple rounds of testing to find a voltage threshold at which the electronics device, or sensitive components specifically, may begin to fail. At the same time, failure to adequately test an electronics device may lead to failures in the field, costing significant resources to address and correct the issues, which also may act as an incentive for a manufacturer to specify a compliance policy that exceeds the minimum standards that may be set by any one jurisdiction.

It may therefore be useful to provide a method or system to build a product model that may indicate an electrostatic discharge (ESD) sensitivity level. Such a method or system may identify sensitive components of an electronics device from existing modelling of the device and also obtain “ESD metadata” from an ESD database or other shared storage that may store information associated with identified sensitive components, such as voltage levels from regulatory standards or information from manufacturer operating manuals or existing 3D models of devices, along with historical information about ESD testing that may be on file regarding the electronics device or specific components, that may be leveraged by the method or system. An ESD voltage threshold may be determined from the ESD metadata, which may indicate a voltage level at which it may be predicted that functionality a component or the electronics device in general may be sufficiently disrupted that the electronics device no longer meets a relevant requirement. The prediction of a threshold may finally be applied to a model that may be generated by the method or system and indicate specific sensitive components along with determined ESD voltage thresholds for each sensitive component. Such a method or system may present known information about an electronics device to a compliance professional and greatly enhance the efficiency of an ESD testing regime by removing many parts of the process that may conventionally be done manually. Also, in addition to presenting findings and predictions to a human, the generated model with an indication of sensitive components and ESD voltage thresholds for the sensitive components may further be used by an automated testing system to further boost efficiency of ESD testing and compliance.

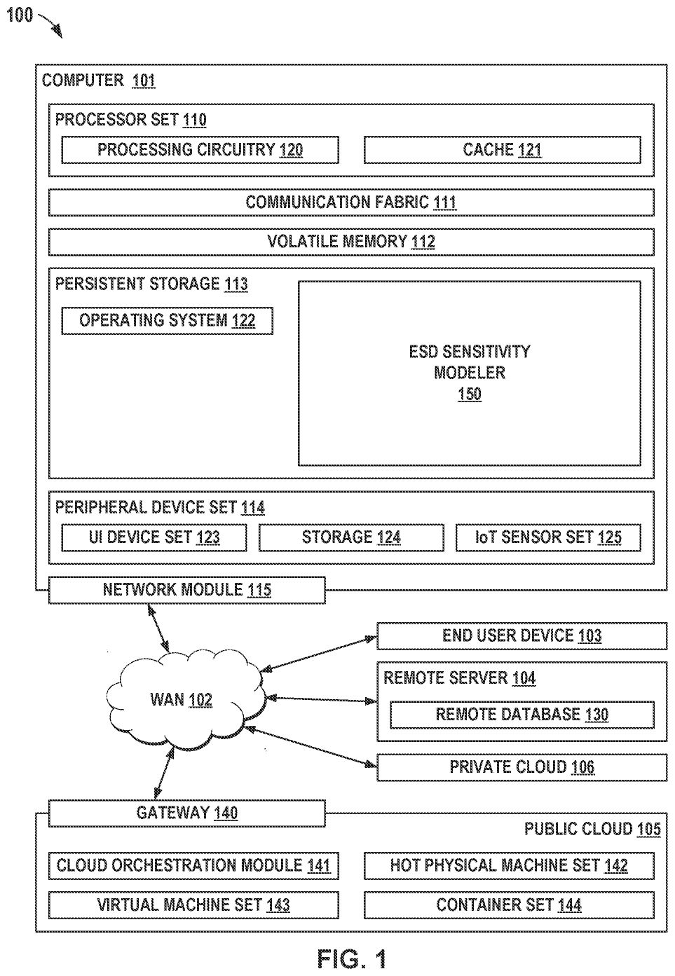

Referring to FIG. 1, computing environment 100 contains an example of an environment for the execution of at least some of the computer code involved in performing the inventive methods, such as ESD sensitivity modeler 150. In addition to ESD sensitivity modeler 150, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and ESD sensitivity modeler 150, as identified above), peripheral device set 114 (including user interface (UI), device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in software installation guidance ESD sensitivity modeler 150 in persistent storage 113.

Communication fabric 111 is the signal conduction paths that allow the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, the volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid-state storage devices. Operating system 122 may take several forms, such as various known proprietary operating systems or open-source Portable Operating System Interface-type operating systems that employ a kernel. The code included in software installation guidance ESD sensitivity modeler 150 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End User Device (EUD) 103 is any computer system that is used and controlled by an end user (for example, a customer of an enterprise that operates computer 101) and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of VCEs will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Computer environment 100 may be used to build a product model that indicates an electrostatic discharge (ESD) sensitivity level. In particular, the ESD sensitivity modeler 150 may identify components in a model of an electronics device that may be considered to be especially sensitive to ESD, either manually through an indication or other input from a user or in an automated fashion through known information about the electronics device and the components thereof, where the known information may be data from the manufacturer of the component, such as a manual or individual component specifications, or prior testing of electronics devices that may be similar or use the same or similar components. As described herein, sensitive components of an electronics device may refer to specific electronics components or circuits that may be present on a printed circuit board within the electronics device and may be seen on a schematic of the electronics device. However, identifying sensitive components may also include identifying the physical location of the component within the electronics device, or mapping a sensitive component to a location. For example, because normal ESD testing is conducted with the relevant covers applied, it may only be known that ESD applied to specific parts of the top surface of the electronics device cause failure conditions by way of ESD energy coupling to sensitive components. In this example, the area on the surface where ESD may be applied, and failure conditions noted, would be noted as a “sensitive component,” even though a specific circuit or electronics component may be at fault.

Once the sensitive components are identified, the ESD sensitivity modeler 150 may obtain “ESD metadata,” or specific information related to ESD that is relevant to the sensitivity of the components or the electronics device as a whole. The source for the ESD metadata may be an ESD database or other shared storage, e.g., remote database 130, which may hold data that may be selected from a group consisting of the known information about the electronics device or individual components and regulatory specifications, which may indicate specifics about testing conditions, e.g., possible failure states, and voltage levels that may be required for compliance. The ESD metadata may be used to determine an ESD voltage threshold for each identified sensitive component, where the voltage threshold may represent a level at which specific sensitive components begin to fail or exhibit behavior that may be considered faulty. Alternatively, the ESD voltage threshold may represent a maximum level up to which a sensitive component can safely operate in the presence of ESD. To calculate the ESD voltage threshold, a machine learning model may be trained using the ESD metadata, such that the machine learning model may predict the threshold using prior testing results or the other ESD metadata mentioned above. Using the calculated, or predicted, ESD voltage threshold information, the ESD sensitivity modeler 150 may generate an enhanced model of the electronic device that indicates the identified sensitive components and the determined ESD voltage threshold at the physical location that is associated with the sensitive component. It should be noted that this information may be added to an existing model of the electronics device if one already exists or else a complete three-dimensional (3D) model of the electronics device using the described indicators of ESD voltage threshold may be created by the modeler 150.

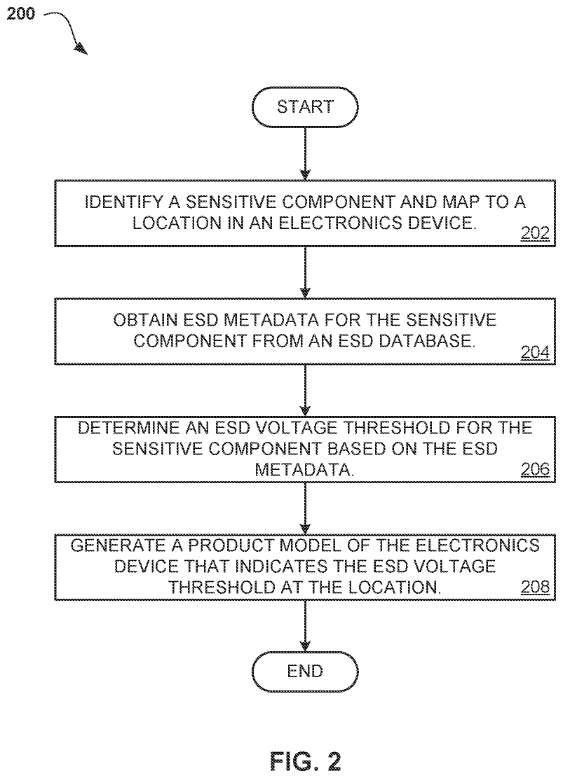

Referring to FIG. 2, an operational flowchart illustrating a process 200 that builds a product model that indicates an electrostatic discharge (ESD) sensitivity level is depicted according to at least one embodiment. At 202, a sensitive component may be identified from a model of a computing device, where identification may include mapping the sensitive component to a physical location within the electronics device. As an example, a rack-mounted computer system may be the electronics device to be tested for ESD and the power supply may be an identified sensitive component. In this example, the physical location of the power supply in the computer system may be associated with the identification as a sensitive component. In another example, a specific electronics component or circuit, such as an expansion video card within a computer system, or the microprocessor or specific resistors or capacitors, may be specifically identified and associated with a location within the computer system. It should also be noted that the location itself may be identified as a sensitive component. For instance, it may be known that the top surface of a medical device may be particularly sensitive to electrostatic discharge. In this scenario, the affected electronics may not be known specifically but the top surface may be identified as a sensitive component for the purposes of this disclosure. In addition, the model of the electronics device may include technical drawings or images of the physical electronics device, in which case the drawings or images may be parsed into spaces accessible to humans, which may further be assessed for ESD sensitivity by analyzing physical shape of surfaces, e.g., curvature of surfaces, or other physical characteristics and then mapping the location as described above.

It is important to note that a sensitive component is not necessarily limited to those components or mapped locations that are the most susceptible in past testing but may also include components or locations that are required for testing by a regulatory specification, which may explicitly state regions of an electronic device that must be tested or lay out a framework for identification of sensitive components. As such, the identification of a sensitive component may also be accomplished through obtaining and understanding a regulatory standard related to ESD discharge.

In an embodiment, a supervised machine learning model may be trained to predict ESD sensitive components, or test points, for the electronics device. One or more of the following machine learning algorithms may be used: logistic regression, naive Bayes, support vector machines, deep neural networks, random forest, decision tree, gradient-boosted tree, multilayer perceptron. In an embodiment, an ensemble machine learning technique may be employed that uses multiple machine learning algorithms together to assure better classification when compared with the classification of a single machine learning algorithm. In this embodiment, training data for the model may include technical specifications or drawings that may be available for the electronic device. The training data may include relevant regulatory specifications, where testing levels may be learned and also standards for detection of failure conditions in the electronics device. Also included in the training data may be technical specifications for the electronics devices and components, including technical drawings of the electronics device that may be parsed for sensitive locations. The training data may be collected from a single electronics device or from multiple electronics devices, e.g., similar models or versions of the electronics device or other electronics devices that may use the same or similar components, over a longer period of time. The results may be stored in a database so that the data is most current, and the output would always be up to date.

At 204, ESD metadata associated with the sensitive component may be obtained from an ESD database or other shared storage, which may store a variety of data, including known information from a manufacturer, such as an operating manual or other technical documentation, regulatory specs and historical ESD test reports for the electronic device overall or the sensitive component specifically. One of ordinary skill in the art will recognize that ESD metadata may take a variety of forms, such as specific information about prior ESD testing of the same or similar electronic device, where specific device behavior may be noted at a variety of ESD voltage levels, or technical specifications of certain electronics components or sub-products, e.g., a power supply or third-party expansion card in a computer system. ESD metadata may extend to an electromagnetic (EM) profile of the overall device that may indicate location and levels of electric current to, from and within the electronic device, that may be used to establish an EM profile of the electronic device and further show any sensitivity of the device to ESD. In addition, ESD metadata is not necessarily limited to electronic characteristics of the electronics device but may also include physical characteristics, e.g., dimensions of the electronic device or materials used in the construction of the electronic device, that may indicate sensitivity to ESD discharge testing.

At 206, an ESD voltage threshold may be determined for the sensitive component based on the ESD metadata. The ESD voltage threshold may represent a voltage level at which ESD testing begins to cause failure conditions in the electronics device, as defined in regulatory specifications, or may represent an ESD voltage level that an electronics device may withstand, using the maximum level described in a regulatory specification as a guide. For instance, the ESD voltage threshold may be displayed as “8.5 kV” for a given sensitive component, where the specification indicates that testing must proceed up to 8 kV, in which case the sensitive component would be expected to pass the testing. However, the threshold in this case could also be displayed as “8 kV,” indicating the maximum level that should be applied to the sensitive component. The inputs to the determination of ESD voltage threshold may be the same as the identification of sensitive components and the ESD metadata but may also include the regulatory specifications of multiple jurisdictions, such that multiple ESD voltage thresholds may be displayed for each of the specifications, where maximum ESD testing levels may vary. That is to say, in the example above, the threshold of “8 kV” may be displayed as “4 kV” for a second jurisdiction that may require lower testing levels. It should also be noted that the regulatory specification may have varying levels for different types of equipment, e.g., computer equipment or hair dryers or home appliances, etc., and therefore the determination of ESD voltage threshold may take this distinction into account in displaying the ESD voltage threshold. One of ordinary skill in the art will recognize that multiple versions of an electronics device may be manufactured for separate markets, and this distinction may also be taken into account by applying the appropriate regulatory standard to the version of the electronics device.

In an embodiment, a supervised machine learning model may be trained to predict the ESD voltage threshold for a sensitive component or electronics device based on regulatory specifications and information about historical testing. One or more of the following machine learning algorithms may be used: logistic regression, naive Bayes, support vector machines, deep neural networks, random forest, decision tree, gradient-boosted tree, multilayer perceptron. In an embodiment, an ensemble machine learning technique may be employed that uses multiple machine learning algorithms together to assure better classification when compared with the classification of a single machine learning algorithm. In this embodiment, training data for the model may include any prior ESD test reports that may be available for the sensitive component, including but not limited to testing on the electronics device, e.g., a circuit may be used in other electronics devices for which testing data exists or prior versions of the electronics device may use the same circuit. The training data may also include relevant regulatory specifications, where testing levels may be learned and also standards for detection of failure conditions in the electronics device, which may then also be applied back to the prior ESD test reports. The training data may be collected from a single electronics device or from multiple electronics devices over a longer period of time. The results may be stored in a database so that the data is most current, and the output would always be up to date.

At 208, a product model may be generated for the computing device that may include an indicator of the ESD voltage threshold for each sensitive component at each mapped location on the product model. The product model may be a three-dimensional (3D) model that may be a drawing of the electronics device with the ESD voltage threshold printed next to each sensitive component or may take the form of a model that may be transmitted to an ESD test simulation system. For instance, if the top surface has more than one sensitive component identified with separate ESD voltage thresholds, then a product model may include an indicator of each mapped location that may include the ESD voltage threshold. One of ordinary skill in the art will recognize that there are many ways to indicate both a mapped location and the ESD voltage threshold on a product model. It should be noted that multiple versions of the product model may be produced based on the geographical region or jurisdiction that may be determined from the regulatory specification. As an example, a product may be sold in South Korea and be subject to one ESD specification and then also sold in the European Union (EU), which may have different ESD regulations and thus a different ESD voltage threshold. In this example, separate product models may be produced for each geographic region that may indicate different ESD voltage thresholds or, alternatively, the single product model may include separate ESD voltage thresholds for the same electronics device for each geographical region or jurisdiction.

Included at this step may be a feedback mechanism, whereby the interaction of a user with the product model may be monitored and used to refine the product model. Included at this step is the ability of the user to make manual decisions about the product model such as whether or not the indicators of sensitive components, mapped locations or ESD voltage thresholds are correct. The interaction of such users with the product model would be monitored and updates to the product model, including the identification of additional sensitive components and mapped locations, as well as modifying the ESD voltage threshold or removing sensitive locations and mapped locations from the product model, may be made based on the user interactions.

One of ordinary skill in the art will recognize that appropriate files may be generated at this step, such that a product model could be stored in relevant indexed storage such as a database and also sent to an ESD test simulation system using an appropriate file format. The product model may also be saved in file formats that are suitable for later retrieval by users as it is not required for the user to immediately utilize the product model in performing ESD testing. The product model may further be saved for use as training data in the machine learning models as described above, e.g., the product model may itself be ESD metadata as described herein.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A computer-implemented method for building a product model that indicates an electrostatic discharge (ESD) sensitivity level, the computer-implemented method comprising:
identifying a sensitive component in an electronics device and mapping the sensitive component to a location in the electronics device;
obtaining ESD metadata for the sensitive component from an ESD database;
determining an ESD voltage threshold for the sensitive component based on the ESD metadata for the sensitive component; and
generating a product model of the electronics device, wherein the product model includes a plurality of sensitive components mapped to a plurality of locations in the electronics device and an indication of the ESD voltage threshold for each sensitive component at a respective mapped location in the electronic device.

2. The computer-implemented method of claim 1, further comprising:
transmitting the product model to an ESD test simulation system; and
applying, by the ESD test simulation system, ESD discharges to each respective mapped location in the electronics device.

3. The computer-implemented method of claim 1, further comprising:
monitoring user interactions with the product model, wherein a user selects the location in the electronics device on the product model; and
mapping the sensitive component to the location in the electronics device based on the user interactions.

4. The computer-implemented method of claim 1, further comprising:
identifying an ESD regulatory specification in the ESD metadata, wherein the ESD regulatory specification includes a geographical region; and
modifying the ESD voltage threshold based on the geographical region of the ESD regulatory specification.

5. The computer-implemented method of claim 1, wherein the identifying the sensitive component in the model of the electronics device uses a machine learning model that predicts ESD test points for the electronics device based on an ESD regulatory specification and technical specifications of the electronics device.

6. The computer-implemented method of claim 1, wherein the determining the ESD voltage threshold for the sensitive component based on the ESD metadata for the sensitive component uses a machine learning model that predicts an ESD testing level for the sensitive component based on an ESD regulatory specification and historical ESD testing information for the electronics device.

7. The computer-implemented method of claim 1, wherein the ESD database comprises data selected from a group consisting of: historical ESD test data for the sensitive component, historical ESD test data for the electronics device, and a regulatory specification related to ESD.

8. A computer system for building a product model that indicates an electrostatic discharge (ESD) sensitivity level, the computer system comprising:
one or more processors, one or more computer-readable memories, and one or more computer-readable storage media;
program instructions, stored on at least one of the one or more computer-readable storage media for execution by at least one of the one or more processors via at least one of the one or more computer-readable memories, to identify a sensitive component in an electronics device and mapping the sensitive component to a location in the electronics device;
program instructions, stored on at least one of the one or more computer-readable storage media for execution by at least one of the one or more processors via at least one of the one or more computer-readable memories, to obtain ESD metadata for the sensitive component from an ESD database;
program instructions, stored on at least one of the one or more computer-readable storage media for execution by at least one of the one or more processors via at least one of the one or more computer-readable memories, to determine an ESD voltage threshold for the sensitive component based on the ESD metadata for the sensitive component; and
program instructions, stored on at least one of the one or more computer-readable storage media for execution by at least one of the one or more processors via at least one of the one or more computer-readable memories, to generate a product model of the electronics device, wherein the product model includes a plurality of sensitive components mapped to a plurality of locations in the electronics device and an indication of the ESD voltage threshold for each sensitive component at a respective mapped location in the electronic device.

9. The computer system of claim 8, further comprising:
program instructions, stored on at least one of the one or more computer-readable storage media for execution by at least one of the one or more processors via at least one of the one or more computer-readable memories, to transmit the product model to an ESD test simulation system; and
program instructions, stored on at least one of the one or more computer-readable storage media for execution by at least one of the one or more processors via at least one of the one or more computer-readable memories, to apply, by the ESD test simulation system, ESD discharges to each respective mapped location in the electronics device.

10. The computer system of claim 8, further comprising:
program instructions, stored on at least one of the one or more computer-readable storage media for execution by at least one of the one or more processors via at least one of the one or more computer-readable memories, to monitor user interactions with the product model, wherein a user selects the location in the electronics device on the product model; and
program instructions, stored on at least one of the one or more computer-readable storage media for execution by at least one of the one or more processors via at least one of the one or more computer-readable memories, to map the sensitive component to the location in the electronics device based on the user interactions.

11. The computer system of claim 8, further comprising:
program instructions, stored on at least one of the one or more computer-readable storage media for execution by at least one of the one or more processors via at least one of the one or more computer-readable memories, to identify an ESD regulatory specification in the ESD metadata, wherein the ESD regulatory specification includes a geographical region; and
program instructions, stored on at least one of the one or more computer-readable storage media for execution by at least one of the one or more processors via at least one of the one or more computer-readable memories, to modify the ESD voltage threshold based on the geographical region of the ESD regulatory specification.

12. The computer system of claim 8, wherein the identifying the sensitive component in the model of the electronics device uses a machine learning model that predicts ESD test points for the electronics device based on an ESD regulatory specification and technical specifications of the electronics device.

13. The computer system of claim 8, wherein the determining the ESD voltage threshold for the sensitive component based on the ESD metadata for the sensitive component uses a machine learning model that predicts an ESD testing level for the sensitive component based on an ESD regulatory specification and historical ESD testing information for the electronics device.

14. The computer system of claim 8, wherein the ESD database comprises data selected from a group consisting of: historical ESD test data for the sensitive component, historical ESD test data for the electronics device, and a regulatory specification related to ESD.

15. A computer program product for building a product model that indicates an electrostatic discharge (ESD) sensitivity level, the computer program product comprising:
one or more computer-readable storage media;
program instructions, stored on at least one of the one or more computer-readable storage media, to identify a sensitive component in an electronics device and mapping the sensitive component to a location in the electronics device;
program instructions, stored on at least one of the one or more computer-readable storage media, to obtain ESD metadata for the sensitive component from an ESD database;
program instructions, stored on at least one of the one or more computer-readable storage media, to determine an ESD voltage threshold for the sensitive component based on the ESD metadata for the sensitive component; and
program instructions, stored on at least one of the one or more computer-readable storage media, to generate a product model of the electronics device, wherein the product model includes a plurality of sensitive components mapped to a plurality of locations in the electronics device and an indication of the ESD voltage threshold for each sensitive component at a respective mapped location in the electronic device.

16. The computer program product of claim 15, further comprising:
program instructions, stored on at least one of the one or more computer-readable storage media, to transmit the product model to an ESD test simulation system; and
applying, by the ESD test simulation system, ESD discharges to each respective mapped location in the electronics device.

17. The computer program product of claim 15, further comprising:
program instructions, stored on at least one of the one or more computer-readable storage media, to monitor user interactions with the product model, wherein a user selects the location in the electronics device on the product model; and
program instructions, stored on at least one of the one or more computer-readable storage media, to map the sensitive component to the location in the electronics device based on the user interactions.

18. The computer program product of claim 15, further comprising:
program instructions, stored on at least one of the one or more computer-readable storage media, to identify an ESD regulatory specification in the ESD metadata, wherein the ESD regulatory specification includes a geographical region; and
program instructions, stored on at least one of the one or more computer-readable storage media, to modify the ESD voltage threshold based on the geographical region of the ESD regulatory specification.

19. The computer program product of claim 15, wherein the identifying the sensitive component in the model of the electronics device uses a machine learning model that predicts ESD test points for the electronics device based on an ESD regulatory specification and technical specifications of the electronics device.

20. The computer program product of claim 15, wherein the determining the ESD voltage threshold for the sensitive component based on the ESD metadata for the sensitive component uses a machine learning model that predicts an ESD testing level for the sensitive component based on an ESD regulatory specification and historical ESD testing information for the electronics device.
